(19) United States
(12) Patent Application Publication
(10) Pub. No.: US 2025/0324644 A1
(43) Pub. Date: Oct. 16, 2025

(54) HIGH-QUALITY GAN HEMT POWER SEMICONDUCTOR EPITAXY WAFER WITH 3D NITRIDE STRUCTURE AND MANUFACTURING METHOD OF THE SAME

(71) Applicant: WAVELORD CO., LTD, Gyeonggi-do (KR)

(72) Inventors: June O SONG, Gyeonggi-do (KR); Hyun Chul LIM, Gyeonggi-do (KR); Young Hun HAN, Gyeonggi-do (KR); Hyung Sun YUN, Gyeonggi-do (KR)

(21) Appl. No.: 19/176,467

(22) Filed: Apr. 11, 2025

(30) Foreign Application Priority Data
Apr. 12, 2024 (KR) 10-2024-0049555
May 31, 2024 (KR) 10-2024-0071344

(51) Int. Cl. H10D 30/47; H01L 21/02; H01L 23/373; H10D 30/01; H10D 62/82; H10D 62/832

(52) U.S. Cl. CPC H10D 30/475; H01L 21/02378; H01L 21/02381; H01L 21/02458; H01L 21/0254; H01L 21/02614; H01L 21/02672; H01L 23/3738; H10D 30/015; H10D 62/82; H10D 62/8325

(57) ABSTRACT

Embodiments according to the present invention provide a high-quality GaN HEMT power semiconductor epitaxy wafer having a three-dimensional nitride structure, comprising: a growth substrate; a nucleation region formed on the growth substrate; and a three-dimensional nitride structure region formed on the nucleation region and having a composition ratio that varies along a lateral direction.

### CROSS-REFERENCE TO RELATED APPLICATIONS

This application claims priority to Korean Patent Application Nos. 10-2024-0049555, filed on Apr. 12, 2024 and 10-2024-0071344, filed on May 31, 2024. The entire disclosure of the applications identified in this paragraph is incorporated herein by reference.

### FIELD

The present invention relates to a GaN HEMT power semiconductor epitaxy wafer and a method for manufacturing the same, in which a three-dimensional nitride structure is introduced to improve heat dissipation characteristics and epitaxy crystal quality.

### BACKGROUND

GaN HEMT epitaxy wafers, which are used as core components of power amplifiers, which are key components of radio frequency communication modules, and as key materials for converters and inverters for high-speed switching, are manufactured by depositing a film on an electrically insulating silicon carbide (SiC) or silicon (Si) substrate with high heat transfer properties.

GaN HEMT devices generate a large amount of heat during operation, which has a significant impact on device reliability and lifespan as well as module quality. Therefore, a solution technology that enhances heat dissipation is essential.

The conventional HEMT (High Electron Mobility Transistor) for GaN power semiconductors known so far has a structure in which an AlN nucleation region, an Al(1−x)Ga(x)N stress control region, a GaN buffer region, a GaN channel region, and an Al(1−x)Ga(x)N barrier region are stacked on a SiC or Si growth substrate.

The GaN buffer region forms a high-resistance layer to reduce vertical leakage current. To this end, the buffer region is grown by intentionally doping it with iron (Fe) or carbon (C). However, doping with impurities such as iron (Fe) or carbon (C) has the problem of deteriorating the film formation quality in the GaN buffer region.

Accordingly, since the thickness of the conventional GaN HEMT device increases, there is a problem of worsening the heat dissipation characteristics of the GaN HEMT device and degrading the device characteristics.

As an approach to developing a high heat dissipation GaN HEMT device, it is desirable to minimize the thickness, but to do so, there remains the task of implementing a thin GaN HEMT device structure while solving the problem of deterioration of crystal quality due to thickness reduction.

### DISCLOSURE

### Technical Problem

The present invention aims to provide a high-quality GaN HEMT power semiconductor epitaxy wafer having a three-dimensional nitride structure capable of minimizing heat generated during operation of a GaN HEMT device or rapidly and easily releasing the generated heat to improve reliability, lifespan, and module quality of the device, and a method for manufacturing the same.

### Technical Solution

Embodiments according to the present invention provide a high-quality GaN HEMT power semiconductor epitaxy wafer having a three-dimensional nitride structure, comprising: a growth substrate; a nucleation region formed on the growth substrate; and a three-dimensional nitride structure region formed on the nucleation region and having a composition ratio that varies along a lateral direction.

In embodiments according to the present invention, the thickness of the three-dimensional nitride structure region is 100 nm or less.

In embodiments according to the present invention, the composition ratio change tendency appearing along the lateral direction of the three-dimensional nitride structure region is approximated to a wave curve having a period of 100 nm or less.

In embodiments according to the present invention, the growth substrate is SiC or Si, the nucleation region is AlN, and the three-dimensional nitride structure region is formed of AlInGaN.

Embodiments according to the present invention further comprise a channel region formed of GaN on the three-dimensional nitride structure region; a barrier region formed of AlInGaN or AlScGaN on the channel region;

Embodiments according to the present invention provide a method for manufacturing a high-quality GaN HEMT power semiconductor epitaxy wafer having a three-dimensional nitride structure, comprising: a step of preparing a growth substrate; a step of forming a nucleation region on the growth substrate; and a step of forming a three-dimensional nitride structure region having a composition ratio that changes along a lateral direction using a precursor cluster in which elements of a nitride material are aggregated on the nucleation region.

In embodiments of the manufacturing method according to the present invention, the step of forming the three-dimensional nitride structure region may be performed repeatedly two or more times.

In embodiments of the manufacturing method according to the present invention, the step of forming the three-dimensional nitride structure region comprises a step of forming a three-dimensional nitride structure, which is a precursor cluster having a three-dimensional shape, by causing group III elements (Al, Ga, In) of the nitride material to aggregate with each other without supplying a nitrogen source on the nucleation region; and a step of forming a 3DNS in which a nitrogen source is supplied to the three-dimensional nitride structure to form the three-dimensional nitride structure region in which the three-dimensional nitride structure is recrystallized into a single crystal.

In embodiments of the manufacturing method according to the present invention, the step of forming the three-dimensional nitride structure forms the three-dimensional nitride structure by preflowing a source of group 3 elements (Al, Ga, In) of the nitride material, and the step of forming a 3DNS forms a recrystallized three-dimensional nitride structure region by supplying ammonia (NH₃) gas.

In embodiments of the manufacturing method according to the present invention, the method may further comprise a step of forming a device region (active region) including a channel region and a barrier region on the three-dimensional nitride structure region.

### Advantageous Effects

According to the present invention, the lattice constant difference between the nucleation region and the channel region is alleviated by the three-dimensional nitride structure (or structure region). In addition, crystal defects such as dislocations are offset and annihilated. Therefore, it plays a role in improving the crystal quality.

According to the present invention, the channel region grown by the continuous subsequent process is improved in quality by the three-dimensional nitride structure (or structure region). In addition, the HEMT epitaxy structure can be made ultra-thin. Therefore, it enables the production of a HEMT device with high heat dissipation.

### BRIEF DESCRIPTION OF DRAWINGS

FIG. 1 is a drawing showing an embodiment of a high-quality GaN HEMT power semiconductor epitaxy wafer through the introduction of a three-dimensional nitride structure according to the present invention.

FIG. 2 is an enlarged photograph of area A of FIG. 1 in the cross-section of an actually manufactured high-quality GaN HEMT power semiconductor epitaxy wafer through the introduction of a three-dimensional nitride structure.

FIGS. 3, 4, 5, 6 and 7 are drawings showing an embodiment of a method for manufacturing a high-quality GaN HEMT power semiconductor epitaxy wafer through the introduction of a three-dimensional nitride structure according to the present invention.

### DETAILED DESCRIPTION

Hereinafter, embodiments of High-quality GaN HEMT power semiconductor epitaxy wafer with 3D nitride structure and manufacturing method of the same according to the present invention will be described in detail with reference to the drawings.

The terms used below have been selected for convenience of explanation, and should be appropriately interpreted in a meaning that is consistent with the technical idea of the present invention without being limited to the dictionary meaning.

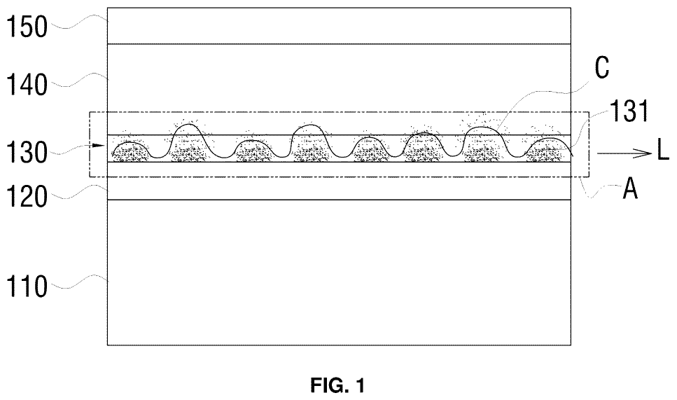

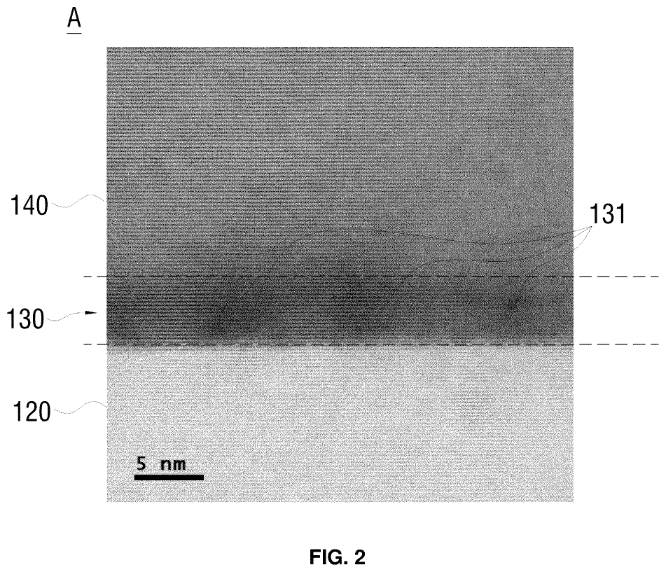

Referring to FIG. 1, a high-quality GaN HEMT power semiconductor epitaxy wafer through introduction of a three-dimensional nitride structure according to the present embodiment comprises a growth substrate (110), a nucleation region (120), and a three-dimensional nitride structure region (130).

The growth substrate (110) is preferably formed of SiC or Si, and the nucleation region (120) is preferably formed of AIN on the growth substrate.

The three-dimensional nitride structure region (130) is formed on the nucleation region (120) and is formed so that the composition ratio (C) changes along the lateral direction (L).

At this time, the three-dimensional nitride structure region (130) is formed as a discontinuous and non-uniform nano-scale dot-shaped structure, and the positions of these dot-shaped structures and other positions are formed with different composition ratios.

That is, the three-dimensional nitride structure region (130) formed of Al(x)In(y)Ga(1−x−y)N has the technical characteristic of being formed such that x and y are different in the lateral direction.

The present embodiment can improve the epitaxial crystal quality of a channel region formed of a GaN material thereon by employing a three-dimensional nitride structure region.

The three-dimensional nitride structure region plays a role in alleviating the thermo-mechanical stress caused by the difference in lattice constant between the AlN nucleation region and the GaN channel region. It also cancels out and eliminates crystal defects such as dislocations. Therefore, it plays a role in improving crystal quality.

The present embodiment further comprises a channel region (140) formed of a GaN material on a three-dimensional nitride structure region through a subsequent post-process, and a barrier region (150) formed of an AlGaN material on the channel region.

The three-dimensional nitride structure region enables the GaN channel region grown thereon to be of high quality, thereby making it possible to fabricate a GaN HEMT device with high heat dissipation by making the GaN HEMT epitaxy structure ultra-thin to less than 700 nm thick.

At this time, it is preferable that the thickness of the three-dimensional nitride structure region according to the present embodiment is formed to be 3 nm or more.

It is preferable that the three-dimensional nitride structure region (130) according to the present embodiment is formed so that the composition ratio change tendency that appears along the lateral direction approximates a wave curve whose period is 100 nm or less.

In this embodiment, the three-dimensional nitride structure region (130) performs the following five major functions.

First, it controls the thermo-mechanical stress of the interface caused by the lattice constant mismatch and the difference in the thermal expansion coefficient between the nucleation region (120) and the channel region (140).

Second, it annihilates the crystal defects and surface defects caused at the interface between the nucleation region (120) and the channel region (140).

Third, it provides a high heat dissipation solution that can maintain the high heat dissipation characteristics of the growth substrate (110).

Fourth, it minimizes the crystal defects while growing the GaN HEMT epitaxy structure having an ultra-thin thickness of 500 nm or less, thereby securing a high-quality GaN channel region and an AlInGaN or AlScGaN barrier region.

Fifth, by removing the iron (Fe) or carbon (C) doped GaN buffer region in the conventional GaN HEMT device, the device characteristics can be maximized.

The mechanism for the main function of the three-dimensional nitride structure region (130) can be interpreted as follows.

When forming a three-dimensional nitride structure region (130), a metal-organic source of group 3 elements (Al, Ga, In) constituting the nitride material, or a [Mg] or [Si] source used as a group 3 nitride dopant, is preflowed without supplying ammonia (NH₃) gas.

At this time, through a pyrolysis reaction, group III elements (Al, Ga, In) form a three-dimensional nitride structure, which is a three-dimensional dot-shaped cluster, around the surface (an unstable surface with high thermodynamic energy) that meets a threading dislocation, which is a crystal defect created from the interface between the growth substrate (110) and the nucleation region (120).

With the surface energy of the nucleation region (120) lowered by the three-dimensional nitride structure, crystallization proceeds through the supplied ammonia (NH₃) gas, creating a surface in a thermodynamically stable state.

This process is repeated once or several times to form a three-dimensional structure region, that is, to arbitrarily control the change tendency of the composition ratio described above, and this can vary depending on the thickness and composition of the channel region (140) and barrier region (150) grown in the subsequent process.

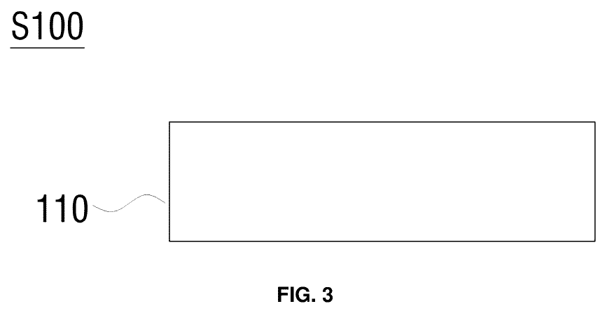

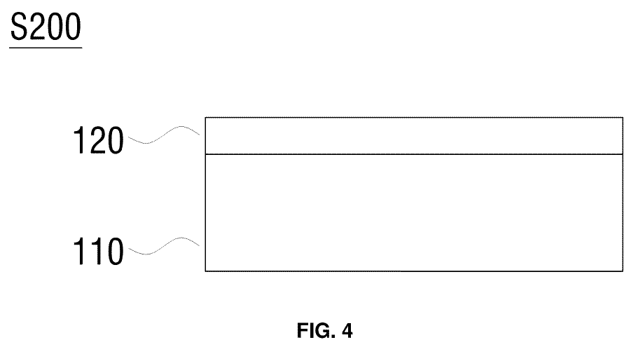

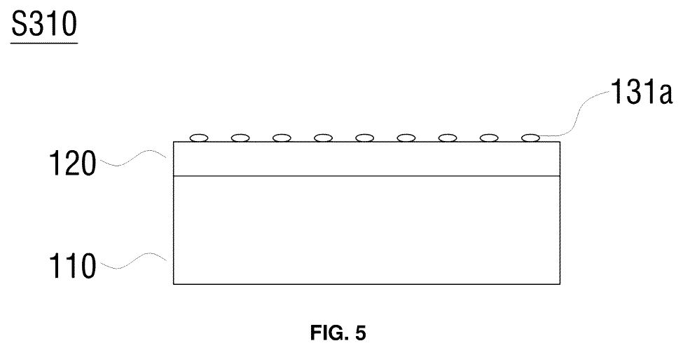

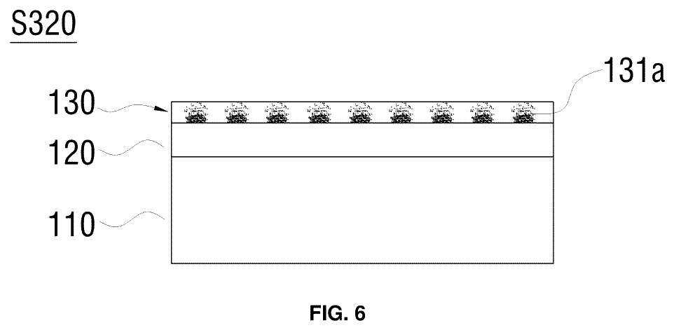

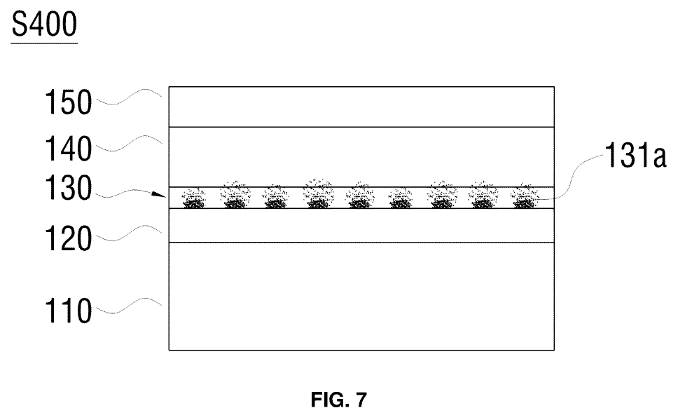

Next, according to FIGS. 3 to 7, the method for manufacturing a high-quality GaN HEMT power semiconductor epitaxy wafer with 3D nitride structure according to the present embodiment comprises a step of preparing a growth substrate (S100), a step of forming a nucleation region on the growth substrate (S200), and a step of forming a three-dimensional nitride structure region (S300).

The step of preparing a growth substrate (S100) prepares the growth substrate (110) on which the nucleation region is to be formed.

The step of forming a nucleation region (S200) forms the nucleation region (120) on the growth substrate (110).

Next, the step of forming a three-dimensional nitride structure region (S300) forms the 3-dimensional nitride structure region (130) whose composition ratio changes along the lateral direction by using a precursor cluster in which group 3 elements (Al, Ga, In) of the nitride material are aggregated on the surface of the nucleation region (120).

The method of forming the three-dimensional nitride structure region (130) using the above-described precursor cluster can be broadly divided into two steps.

It is preferable that the step of forming a three-dimensional nitride structure region (S300) comprises a step of forming a three-dimensional nitride structure (S310) and a step of forming a 3DNS (S320).

In the step of forming a three-dimensional nitride structure (S310), group 3 elements (Al, Ga, In) of the nitride material are first aggregated to form a three-dimensional nitride structure (131a), which is a three-dimensional precursor cluster, on the nucleation region (120).

The three-dimensional nitride structure (131a) can be formed through preflow of a group 3 element including Al, In, and Ga.

The three-dimensional nitride structure (131a) can be formed through a pyrolysis reaction by preflowing a metal-organic source of group 3 elements (Al, Ga, In) constituting the nitride material without supplying ammonia (NH₃) gas.

Next, the step of forming a 3DNS (S320) supplies a nitrogen source containing ammonia (NH₃) to the three-dimensional nitride structure to form a three-dimensional nitride structure region (130) in which the three-dimensional nitride structure is recrystallized into a single crystal.

At this time, each of the three-dimensional nitride structures (131a) forms the nano-scale dot described above within the three-dimensional nitride structure region (130).

In general, the epitaxial process performs a source preflow in which all elements including the organic metals and gases that constitute the thin film to be grown are flowed into the reaction chamber in advance, and then the main growth including the initial growth (nucleation) and layer growth is performed.

In contrast, the manufacturing method according to the present embodiment first preflows a group 3 element excluding a nitrogen source including ammonia (NH₃), thereby first forming a three-dimensional nitride structure (131a), which is a precursor cluster having a three-dimensional shape as described above.

Next, by flowing a nitrogen source into the reaction chamber, recrystallization can be performed, thereby forming the three-dimensional nitride structure region described above.

In the manufacturing method according to the present embodiment, the step of forming a three-dimensional nitride structure region (S300) may be repeated two or more times.

Accordingly, the thickness increase of the three-dimensional nitride structure region and the composition change tendency in the lateral direction can be changed, thereby implementing five functional enhancement of the three-dimensional nitride structure regions described above.

Meanwhile, the manufacturing method according to the present embodiment comprises a step (S400) of forming a device region including a channel region (140) made of gallium nitride (GaN) as a material and a barrier region (150) made of AlGaN or AlScGaN as a material on a three-dimensional nitride structure region (130).

What is claimed is:

1. A high-quality GaN HEMT power semiconductor epitaxy wafer having a three-dimensional nitride structure, comprising:
a growth substrate;
a nucleation region formed on the growth substrate; and
a three-dimensional nitride structure region formed on the nucleation region and having a composition ratio that varies along a lateral direction.

2. The high-quality GaN HEMT power semiconductor epitaxy wafer having a three-dimensional nitride structure of claim 1, wherein the thickness of the three-dimensional nitride structure region is 100 nm or less.

3. The high-quality GaN HEMT power semiconductor epitaxy wafer having a three-dimensional nitride structure of claim 1, wherein the composition ratio change tendency appearing along the lateral direction of the three-dimensional nitride structure region is approximated to a wave curve having a period of 100 nm or less.

4. The high-quality GaN HEMT power semiconductor epitaxy wafer having a three-dimensional nitride structure of claim 1, wherein the growth substrate is SiC or Si, the nucleation region is AlN, and the three-dimensional nitride structure region is formed of AlInGaN.

5. The high-quality GaN HEMT power semiconductor epitaxy wafer having a three-dimensional nitride structure of claim 4, further comprising:
a channel region formed of GaN on the three-dimensional nitride structure region; and
a barrier region formed of AlInGaN or AlScGaN on the channel region;

6. A method for manufacturing a high-quality GaN HEMT power semiconductor epitaxy wafer having a three-dimensional nitride structure, comprising:
a step of preparing a growth substrate;
a step of forming a nucleation region on the growth substrate; and
a step of forming a three-dimensional nitride structure region having a composition ratio that changes along a lateral direction using a precursor cluster in which elements of a nitride material are aggregated on the nucleation region.

7. The method of claim 6, wherein the step of forming the three-dimensional nitride structure region may be performed repeatedly two or more times.

8. The method of claim 6, wherein the step of forming the three-dimensional nitride structure region comprises
a step of forming a three-dimensional nitride structure, which is a precursor cluster having a three-dimensional shape, by causing group III elements (Al, Ga, In) of the nitride material to aggregate with each other without supplying a nitrogen source on the nucleation region; and
a step of forming a 3DNS in which a nitrogen source is supplied to the three-dimensional nitride structure to form the three-dimensional nitride structure region in which the three-dimensional nitride structure is recrystallized into a single crystal.

9. The method of claim 8, wherein
the step of forming the three-dimensional nitride structure forms the three-dimensional nitride structure by preflowing a source of group 3 elements (Al, Ga, In) of the nitride material, and
the step of forming a 3DNS forms a recrystallized three-dimensional nitride structure region by supplying ammonia (NH₃) gas.

10. The method of claim 6, further comprising:
a step of forming a device region including a channel region and a barrier region on the three-dimensional nitride structure region.
